(19) United States
(12) Patent Application Publication
(10) Pub. No.: US 2023/0377846 A1
(43) Pub. Date: Nov. 23, 2023

(54) WIDE AREA ATMOSPHERIC PRESSURE PLASMA DEVICE

(71) Applicant: CREATING NANO TECHNOLOGIES, INC., TAINAN CITY (TW)

(72) Inventors: Yi-Ming HSU, Tainan City (TW); Liang-Chun WANG, Tainan City (TW); Yung-Hao CHEN, Tainan City (TW); Po-Hsuan CHEN, Tainan City (TW); Shih-Chang WANG, Tainan City (TW); Huang-Wei CHEN, Tainan City (TW)

(21) Appl. No.: 17/664,048

(22) Filed: May 19, 2022

(51) Int. Cl. H01J 37/32

(52) U.S. Cl. CPC H01J 37/3244; H01J 37/32825; H01J 37/32513; H01J 2237/332; H01J 2237/335; H01J 37/32577; H01J 37/3255

(57) ABSTRACT

A wide area atmospheric pressure plasma device includes a metal casing, a metal electrode, and a dielectric layer. The metal casing includes a chamber, at least one gas channel, and a plasma jet channel, in which the plasma jet channel is located under the chamber. The metal electrode is disposed within the chamber, is adjacent to the plasma jet channel, and extends along a length direction of the plasma jet channel. An outlet of the gas channel is adjacent to a bottom of the metal electrode, such that a working gas in the gas channel is sprayed towards the bottom of the metal electrode. The dielectric layer wraps the metal electrode.

### BACKGROUND

### Field of Invention

The present disclosure relates to an atmospheric pressure plasma technique, and more particularly to a wide area atmospheric pressure plasma device.

### Description of Related Art

Atmospheric plasma is the plasma generated at or near atmospheric pressure. An atmospheric plasma system has no vacuum apparatus and can continuously process workpieces, so compared with a vacuum plasma system, the atmospheric plasma system has advantages in apparatus and process cost.

According to the different forms of plasma, the atmospheric plasma can be roughly divided into corona discharge, dielectric barrier discharge (DBD), plasma jet, and plasma torch, etc. In order to obtain large area plasma treatment performance, a dielectric barrier discharge technique is often used. Although this technique can achieve an effect of large-area plasma treatment, it has problems such as weak energy, which reduces the process rate, and device discharge.

### SUMMARY

Therefore, one objective of the present disclosure is to provide a wide area atmospheric pressure plasma device, and a metal casing of which is provided with a gas channel to directly guide a working gas to a bottom of a metal electrode adjacent to a plasma jet channel. Therefore, the working gas can be dissociated to form plasma near the plasma jet channel, which prevents plasma from being formed within a chamber of the metal casing, avoids unnecessary waste of power, and makes the plasma more concentrated and closer to a workpiece to be treated, thereby enhancing a plasma treatment effect.

Another objective of then present disclosure is to provide a wide area atmospheric pressure plasma device, which can use a sealing ring to surround and abut against an outer side surface of a dielectric layer so as to seal a chamber of a metal casing, such that it can more effectively prevent plasma from being formed within the chamber.

Still another objective of then present disclosure is to provide a wide area atmospheric pressure plasma device, in which an outlet section of a gas channel includes a reduction portion of a smaller radial dimension adjacent to an outlet. Accordingly, the gas can be compressed first at the reduction portion, and then expanded at the outlet, such that the pressure at the outlet can be slightly lower than the atmospheric pressure, which is beneficial to discharging to dissociate a working gas into plasma.

Yet another objective of then present disclosure is to provide a wide area atmospheric pressure plasma device, in which an outlet end surface of a gas channel is an inclined face or a concave arc face facing a dielectric layer, such that an area of the outlet end surface closer to the dielectric layer is increased, which is beneficial to discharging.

According to the aforementioned objectives, the present invention provides a wide area atmospheric pressure plasma device. The wide area atmospheric pressure plasma device includes a metal casing, a metal electrode, and a dielectric layer. The metal casing includes a chamber, at least one gas channel, and a plasma jet channel, in which the plasma jet channel is located under the chamber. The metal electrode is disposed within the chamber, is adjacent to the plasma jet channel, and extends along a length direction of the plasma jet channel. An outlet of the gas channel is adjacent to a bottom of the metal electrode, such that a working gas in the gas channel is sprayed towards the bottom of the metal electrode. The dielectric layer wraps the metal electrode.

According to one embodiment of the present disclosure, the wide area atmospheric pressure plasma device further includes a sealing ring, in which the sealing ring is embedded in an inner sidewall of the chamber, and surrounds and abuts against an outer side surface of the dielectric layer, and the outlet is located below the sealing ring.

According to one embodiment of the present disclosure, the gas channel includes an outlet section, the outlet section includes a first portion, a second portion, and a third portion connected to each other in sequence, and the outlet is located in the third portion. A radial dimension of the second portion is smaller than a radial dimension of the first portion and a radial dimension of the third portion.

According to one embodiment of the present disclosure, the wide area atmospheric pressure plasma device further includes a metal connection block and a connection member. The metal connection block is electrically connected to the metal electrode. The connection member is disposed on an end portion of the metal connection block, and is configured to connect a power wire and the metal connection block.

According to one embodiment of the present disclosure, an outlet end surface of the gas channel is an inclined face, and the inclined face faces the dielectric layer.

According to one embodiment of the present disclosure, an outlet end surface of the gas channel is a concave arc surface, and the concave arc surface faces the dielectric layer.

According to one embodiment of the present disclosure, the dielectric layer is a circular tube structure.

According to one embodiment of the present disclosure, the dielectric layer is a circular quartz tube.

According to one embodiment of the present disclosure, the dielectric layer is a rectangular-like long box structure.

According to one embodiment of the present disclosure, the dielectric layer is a rectangular-like ceramic long box.

### BRIEF DESCRIPTION OF THE DRAWINGS

The invention can be more fully understood by reading the following detailed description of the embodiment, with reference made to the accompanying drawings as follows:

FIG. 1 is a schematic three-dimensional diagram of a wide area atmospheric pressure plasma device in accordance with one embodiment of the present disclosure;

FIG. 2 is a schematic top view of a wide area atmospheric pressure plasma device in accordance with one embodiment of the present disclosure;

FIG. 3 is a schematic side view of a wide area atmospheric pressure plasma device in accordance with one embodiment of the present disclosure;

FIG. 4 is a schematic bottom view of a wide area atmospheric pressure plasma device in accordance with one embodiment of the present disclosure;

FIG. 5A is a schematic cross-sectional view of the wide area atmospheric pressure plasma device taken along a line A-A of FIG. 3;

FIG. 5B is a schematic enlarged cross-sectional view of a portion A of FIG. 5A;

FIG. 6A is a schematic cross-sectional view of a wide area atmospheric pressure plasma device in accordance with another embodiment of the present disclosure;

FIG. 6B is a schematic enlarged cross-sectional view of a portion B of FIG. 6A;

FIG. 7A is a schematic cross-sectional view of a wide area atmospheric pressure plasma device in accordance with still another embodiment of the present disclosure; and

FIG. 7B is a schematic enlarged cross-sectional view of a portion C of FIG. 7A.

### DETAILED DESCRIPTION

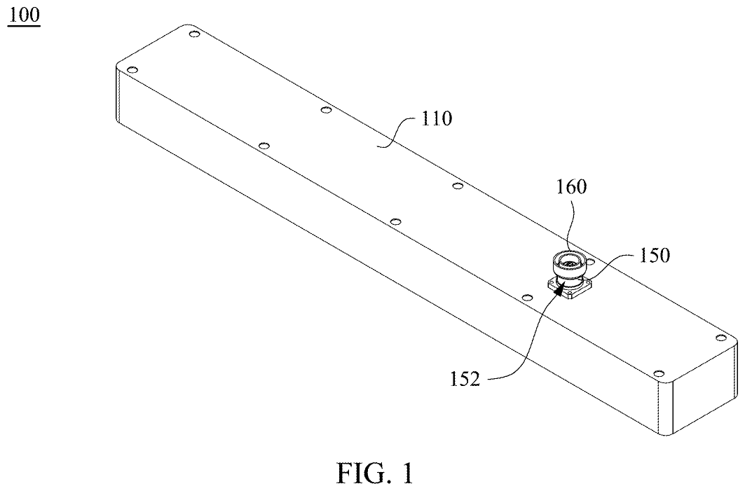

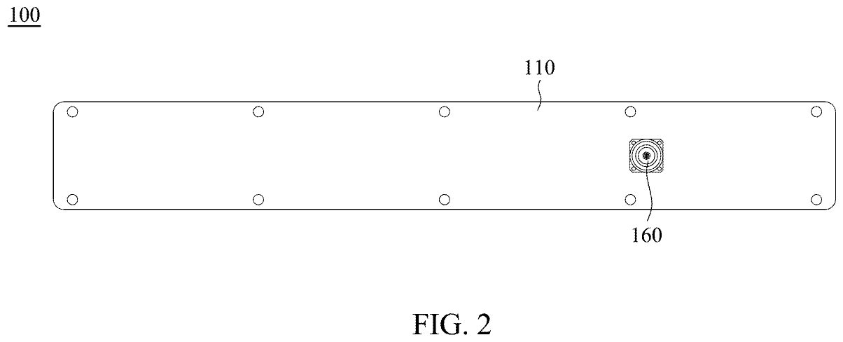

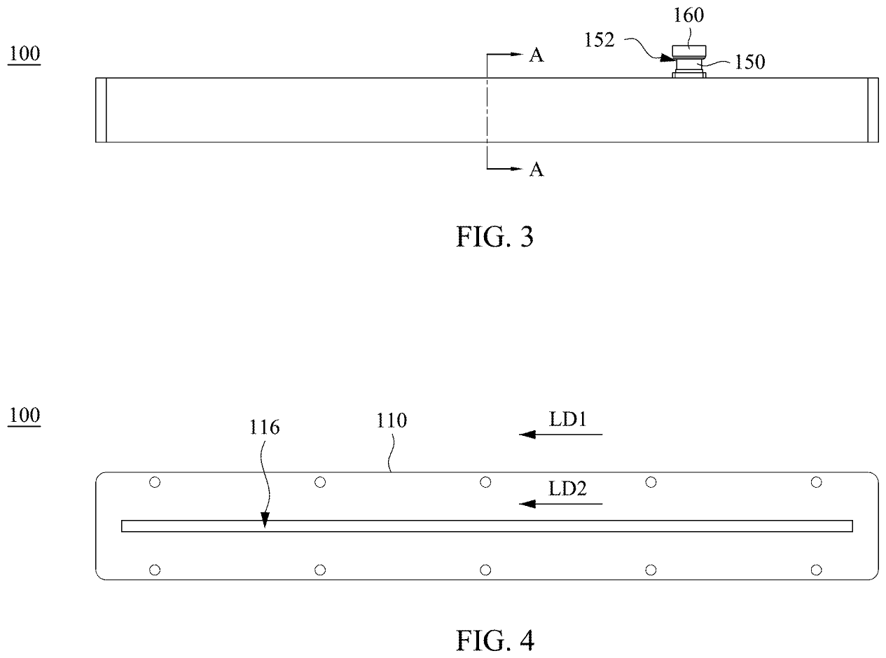

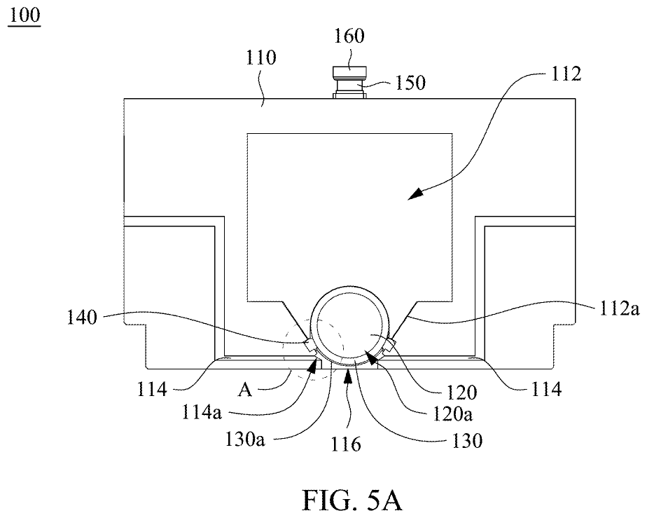

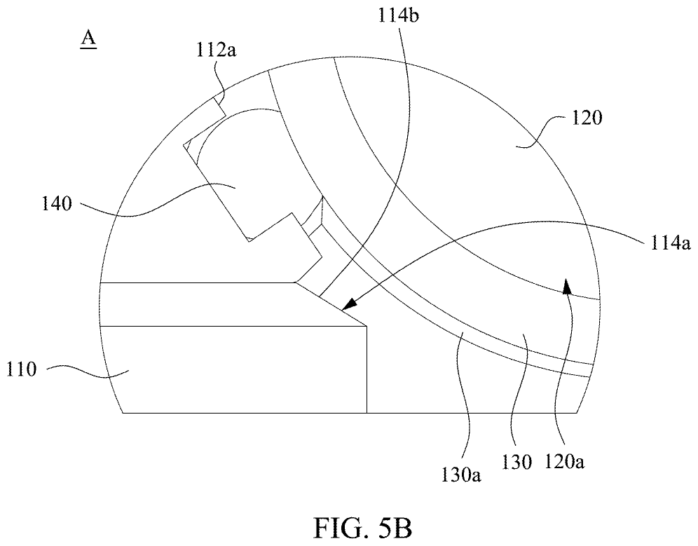

Referring to FIG. 1 through FIG. 5B, FIG. 1 through FIG. 4 are respectively a schematic three-dimensional diagram, a schematic top view, a schematic side view, and a schematic bottom view of a wide area atmospheric pressure plasma device in accordance with one embodiment of the present disclosure, FIG. 5A is a schematic cross-sectional view of the wide area atmospheric pressure plasma device taken along a line A-A of FIG. 3, and FIG. 5B is a schematic enlarged cross-sectional view of a portion A of FIG. 5A. A wide area atmospheric pressure plasma device 100 may be a dielectric barrier discharge plasma device. The wide area atmospheric pressure plasma device 100 may mainly be applied to cleaning and coating. The wide area atmospheric pressure plasma device 100 may mainly include a metal casing 110, a metal electrode 120, and a dielectric layer 130.

The metal casing 110 may be, for example, a long rectangular body. As shown in FIG. 5, the metal casing 110 includes a chamber 112, at least one gas channel 114, and a plasma jet channel 116. The chamber 112 is an inner space of the metal casing 110. The gas channel 114 passes through the metal casing 110 to direct a working gas to the metal electrode 120. In some examples, as shown in FIG. 5A, the metal casing 110 includes various gas channels 114.

As shown in FIG. 4 and FIG. 5A, the plasma jet channel 116 is disposed in and passes through a bottom of the metal casing 110, and is located below the chamber 112. The plasma jet channel 116 can be used for the ejecting of the plasma formed by the wide area atmospheric pressure plasma device 100. In some examples, the plasma jet channel 116 is a long and narrow channel extending along a length direction LD1 of the metal casing 110. The plasma jet channel 116 extends along the length direction LD1 of the metal casing 110, such that a length direction LD2 of the plasma jet channel 116 is parallel to the length direction LD1 of the metal casing 110.

The metal electrode 120 is disposed within the chamber 112 and is adjacent to the plasma jet channel 116. The metal electrode 120 may be a long columnar structure, and may extend along the length direction LD2 of the plasma jet channel 116. For example, as shown in FIG. 5A, the metal electrode 120 may be a cylindrical-like structure. A material of the metal electrode 120 may be any suitable metal, such as aluminum. Also referring to FIG. 5B, an outlet 114a of the gas channel 114 is adjacent to a bottom 120a of the metal electrode 120, such that the gas channel 114 can spray the working gas, which is injected into it, toward the bottom 120a of the metal electrode 120.

The dielectric layer 130 wraps the metal electrode 120. In the example that the metal electrode 120 has a cylindrical-like structure, as shown in FIG. 5A, the dielectric layer 130 may be a circular tube structure, and the metal electrode 120 may be inserted into the dielectric layer 130. In some examples, the dielectric layer 130 a circular quartz tube.

Through the gas channel 114, the working gas can be directly guided to the bottom 120a of the metal electrode 120 adjacent to the plasma jet channel 116, such that the entry of the working gas into the chamber 112 of the metal casing 110 can be greatly reduced, and the working gas can be discharged and dissociated into plasma near the plasma jet channel 116. Therefore, the plasma formed within the chamber 112 of the metal casing 110 can be effectively reduced, unnecessary waste of power can be avoided, the plasma can be more concentrated, and the formed plasma is closer to the workpiece to be processed, thereby enhancing a plasma treatment effect on the workpiece.

In some examples, as shown in FIG. 5B, an outlet end surface 114b of the gas channel 114 may be an inclined surface or a concave arc surface, and the inclined surface or the concave arc surface faces the dielectric layer 130. As a result, compared with a vertical outlet end surface, an area of the outlet end surface 114b closer to the dielectric layer 130 is increased, that is, discharge points are increased, which is beneficial to the discharge of the plasma.

In some examples, as shown in FIG. 5A and FIG. 5B, the wide area atmospheric pressure plasma device 100 further includes a sealing ring 140. The sealing ring 140 may be embedded in an inner sidewall 112a of the chamber 112, and surround and abut against an outer side surface 130a of the dielectric layer 130. That is, the sealing ring 140 is sandwiched between the inner sidewall 112a of the chamber 112 and the outer side surface 130a of the dielectric layer 130 to seal the chamber 112. In addition, the outlet 114a of the gas channel 114 is located below the sealing ring 140. Therefore, the sealing ring 140 can block the circulation of gas between the gas channel 114 and the chamber 112. Accordingly, the working gas flowing out from the outlet 114a of the gas channel 114 will not flow into the chamber 112, and the formation of plasma within the chamber 112 can be prevented more effectively.

Referring to FIG. 1, in some examples, the wide area atmospheric pressure plasma device 100 may further include a metal connection block 150 and a connection member 160. The metal connection block 150 is electrically connected to the metal electrode 120. For example, the metal connection block 150 may be directly connected with the metal electrode 120 to achieve electrical connection. The metal connection block 150 is used to transmit current to the metal electrode 120. A material of the metal connection block 150 may be any suitable metal, such as copper. The connection member 160 is disposed on one end portion 152 of the metal connection block 150. The connection member 160 may be locked on the end portion 152 of the metal connection block 150 by using, for example, screws. The connection member 160 may be used to connect a power wire (not shown) and the metal connection block 150 to transmit the current supplied by a power source to the metal connection block 150. The current is transmitted to the metal electrode 120 through the metal connection block 150, so that the plasma can be easily ignited.

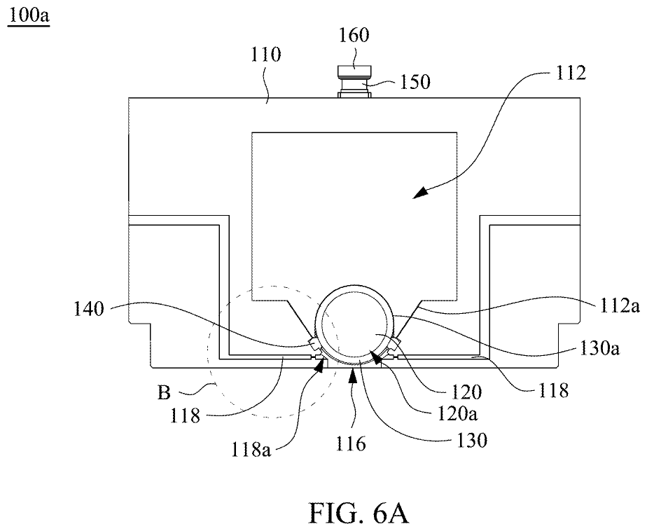

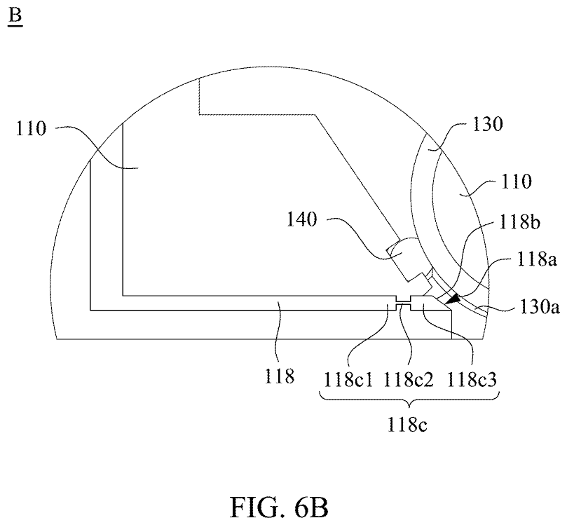

Referring to FIG. 6A and FIG. 6B, FIG. 6A and FIG. 6B are respectively a schematic cross-sectional view of a wide area atmospheric pressure plasma device in accordance with another embodiment of the present disclosure, and a schematic enlarged cross-sectional view of a portion B of FIG. 6A. A structure of a wide area atmospheric pressure plasma device 100a is substantially the same as that of the aforementioned wide area atmospheric pressure plasma device 100. A difference between the wide area atmospheric pressure plasma devices 100a and 100 is that a gas channel 118 of the wide area atmospheric pressure plasma device 100a includes an outlet section 118c that is different from that of the gas channel 114 of the wide area atmospheric pressure plasma device 100.

The outlet section 118c of the gas channel 118 includes a first portion 118c1, a second portion 118c2, and a third portion 118c3 connected to each other in sequence. That is, the second portion 118c2 is located between the first portion 118c1 and the third portion 118c3, and opposite ends of the second portion 118c2 are respectively connected with the first portion 118c1 and the third portion 118c3. An outlet 118a and an outlet end surface 118b are located in the third portion 118c3. A radial dimension of the second portion 118c2 is smaller than a radial dimension of the first portion 118c1 and also smaller than a radial dimension of the third portion 118c3.

When the working gas flows from the first portion 118c1 into the second portion 118c2, the working gas is compressed due to the smaller radial dimension of the second portion 118c2. When the working gas then flows into the third portion 118c3 from the second portion 118c2, an expansion effect is generated because the radial dimension of the third portion 118c3 is larger than that of the second portion 118c2. Thereby, an air pressure at the outlet 118a on the third portion 118c3 can be slightly smaller than the atmospheric pressure, i.e. the gas molecule density at the outlet 118a is lower, which is beneficial to the discharging to dissociate the working gas into plasma, and reduces the attenuation of the plasma.

In the present embodiment, the outlet end surface 118b of the gas channel 118 may also be similar to the outlet end surface 114b of the gas channel 114, and has an inclined surface or a concave arc design.

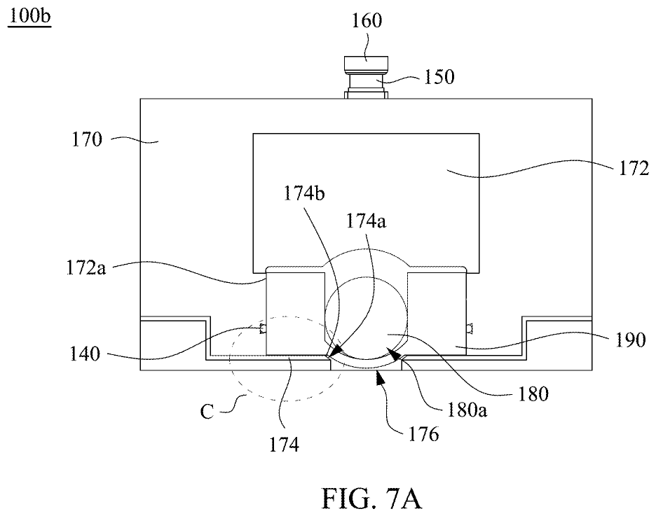

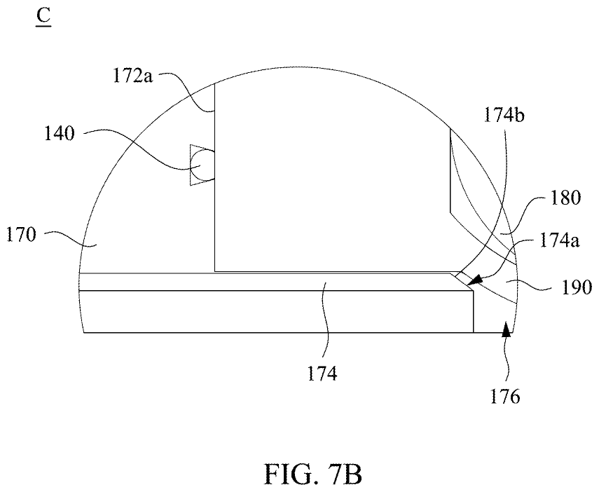

Referring to FIG. 7A and FIG. 7B, FIG. 7A and FIG. 7B are respectively a schematic cross-sectional view of a wide area atmospheric pressure plasma device in accordance with still another embodiment of the present disclosure, and a schematic enlarged cross-sectional view of a portion C of FIG. 7A. Similar to the structure of the aforementioned wide area atmospheric pressure plasma device 100, a wide area atmospheric pressure plasma device 100b mainly includes a metal casing 170, a metal electrode 180, and a dielectric layer 190. A difference between the wide area atmospheric pressure plasma devices 100b and 100 is that a structure of the dielectric layer 190 is different from that of the dielectric layer 130. A structure of the metal casing 170 is modified according to the change of the structure of the dielectric layer 190.

The metal casing 170 may similarly be a long rectangular body. The metal casing 170 includes a chamber 172, one or more gas channel 174, and a plasma jet channel 176. The gas channel 174 passes through the metal casing 170. The plasma jet channel 176 is disposed in and passes through a bottom of the metal casing 170, and is located below the chamber 172. Similarly, the plasma jet channel 176 may be a long and narrow channel extending along a length direction of the metal casing 170.

The metal electrode 180 is disposed within the chamber 172 and is adjacent to the plasma jet channel 176. The dielectric layer 190 wraps the metal electrode 180. In the present embodiment, the dielectric layer 190 is a rectangular-like long box structure. For example, the dielectric layer 190 is a rectangular-like ceramic long box. The metal electrode 180 may be contained within the dielectric layer 190. The metal electrode 180 may be, for example, a cylindrical structure. In addition, an inner sidewall 172a of the chamber 172 connected to the dielectric layer 190 is substantially straight to facilitate the connecting between the dielectric layer 190 and the chamber 172.

An outlet 174a of the gas channel 174 is adjacent to a bottom 180a of the metal electrode 180, such that the gas channel 174 can spray the working gas toward the bottom 180a of the metal electrode 180. Therefore, the working gas can be discharged and dissociated into plasma near the plasma jet channel 176.

In the present embodiment, an outlet end surface 174b of the gas channel 174 may be an inclined surface or a concave arc surface facing the dielectric layer 190. In addition, the gas channel 174 may also have the same design as the outlet section 114c of the gas channel 114. Through these designs, it is easier to discharge to generate plasma.

According to the aforementioned embodiments, one advantage of the present disclosure is that a metal casing of a wide area atmospheric pressure plasma device of the present disclosure is provided with a gas channel to directly guide a working gas to a bottom of a metal electrode adjacent to a plasma jet channel. Therefore, the working gas can be dissociated to form plasma near the plasma jet channel, which prevents plasma from being formed within a chamber of the metal casing, avoids unnecessary waste of power, and makes the plasma more concentrated and closer to a workpiece to be treated, thereby enhancing a plasma treatment effect.

Another advantage of the present disclosure is that a wide area atmospheric pressure plasma device of the present disclosure can use a sealing ring to surround and abut against an outer side surface of a dielectric layer so as to seal a chamber of a metal casing, such that it can more effectively prevent plasma from being formed within the chamber.

Still another advantage of the present disclosure is that an outlet section of a gas channel of a wide area atmospheric pressure plasma device of the present disclosure includes a reduction portion of a smaller radial dimension adjacent to an outlet. Accordingly, the gas can be compressed first at the reduction portion, and then expanded at the outlet, such that the pressure at the outlet can be slightly lower than the atmospheric pressure, which is beneficial to discharging to dissociate a working gas into plasma.

Yet another advantage of the present disclosure is that an outlet end surface of a gas channel of a wide area atmospheric pressure plasma device of the present disclosure is an inclined face or a concave arc face facing a dielectric layer, such that an area of the outlet end surface closer to the dielectric layer is increased, which is beneficial to discharging.

Although the present disclosure has been described in considerable detail with reference to certain embodiments thereof, the foregoing embodiments of the present disclosure are illustrative of the present disclosure rather than limiting of the present disclosure. It will be apparent to those having ordinary skill in the art that various modifications and variations can be made to the present invention without departing from the scope or spirit of the invention. Therefore, the spirit and scope of the appended claims should not be limited to the description of the embodiments contained herein.

What is claimed is:

1. A wide area atmospheric pressure plasma device, comprising:
a metal casing, wherein the metal casing comprises a chamber, at least one gas channel, and a plasma jet channel, and the plasma jet channel is located under the chamber;
a metal electrode disposed within the chamber, adjacent to the plasma jet channel, and extending along a length direction of the plasma jet channel, wherein an outlet of the at least one gas channel is adjacent to a bottom of the metal electrode, such that a working gas in the at least one gas channel is sprayed towards the bottom of the metal electrode; and
a dielectric layer wrapping the metal electrode.

2. The wide area atmospheric pressure plasma device of claim 1, further comprising a sealing ring, wherein the sealing ring is embedded in an inner sidewall of the chamber, and surrounds and abuts against an outer side surface of the dielectric layer, and the outlet is located below the sealing ring.

3. The wide area atmospheric pressure plasma device of claim 1, wherein the at least one gas channel comprises an outlet section, the outlet section comprises a first portion, a second portion, and a third portion connected to each other in sequence, the outlet is located in the third portion, and wherein a radial dimension of the second portion is smaller than a radial dimension of the first portion and a radial dimension of the third portion.

4. The wide area atmospheric pressure plasma device of claim 1, further comprising:
a metal connection block electrically connected to the metal electrode; and
a connection member disposed on an end portion of the metal connection block, and configured to connect a power wire and the metal connection block.

5. The wide area atmospheric pressure plasma device of claim 1, wherein an outlet end surface of the at least one gas channel is an inclined face, and the inclined face faces the dielectric layer.

6. The wide area atmospheric pressure plasma device of claim 1, wherein an outlet end surface of the at least one gas channel is a concave arc surface, and the concave arc surface faces the dielectric layer.

7. The wide area atmospheric pressure plasma device of claim 1, wherein the dielectric layer is a circular tube structure.

8. The wide area atmospheric pressure plasma device of claim 7, wherein the dielectric layer is a circular quartz tube.

9. The wide area atmospheric pressure plasma device of claim 1, wherein the dielectric layer is a rectangular-like long box structure.

10. The wide area atmospheric pressure plasma device of claim 9, wherein the dielectric layer is a rectangular-like ceramic long box.
